(19) United States
(12) Patent Application Publication
(10) Pub. No.: US 2025/0385083 A1
(43) Pub. Date: Dec. 18, 2025

(54) METHODS AND SYSTEM FOR DUTY FACTOR RAMPED TIMED ION IMPLANT MATCHING

(71) Applicant: Applied Materials, Inc., Santa Clara, CA (US)

(72) Inventors: Vincent A. DENO, Wenham, MA (US); Richard G. APPEL, III, Byfield, MA (US); Cuiyang WANG, Andover, MA (US); Deven Raj MITTAL, Middleton, MA (US); James R. MCLANE, Beverly, MA (US); Vikram M. BHOSLE, North Reading, MA (US)

(73) Assignee: Applied Materials, Inc., Santa Clara, CA (US)

(21) Appl. No.: 18/812,431

(22) Filed: Aug. 22, 2024

Related U.S. Application Data
(60) Provisional application No. 63/659,141, filed on Jun. 12, 2024.

(51) Int. Cl. H01J 37/32; H01L 21/265

(52) U.S. Cl. CPC H01J 37/32926; H01J 37/321; H01J 37/32146; H01J 2237/3365; H01L 21/265

(57) ABSTRACT

Disclosed herein is a method for duty factor ramped timed ion implant matching. The method includes receiving, by a processing circuit, a duty cycle parameter from a user interface associated with the processing circuit. The method further includes generating, by the processing circuit, a control signal for a wafer pulse power supply of a plasma doping system to alter a pulse duty cycle of the wafer pulse power supply according to the duty cycle parameter. The method further includes sending, by the processing circuit, the control signal to the wafer pulse power supply to thereby alter a duty cycle of a pulse signal generated by the wafer pulse power supply.

### RELATED APPLICATIONS

This application claims priority to Provisional Patent Application Ser. No. 63/659,141 filed on Jun. 12, 2024, entitled “METHODS AND SYSTEM FOR DUTY FACTOR RAMPED TIMED ION IMPLANT MATCHING,” and incorporated by reference herein in its entirety.

### FIELD OF THE DISCLOSURE

The present disclosure relates generally to semiconductor doping methods. More particularly, the present disclosure relates to a method for altering a duty factor or duty cycle of a semiconductor wafer power supply to implant ions in the wafer.

### BACKGROUND OF THE DISCLOSURE

Plasma processing has been widely used in the semiconductor and other industries for many decades. Plasma processing is used for tasks such as cleaning, etching, milling, and deposition. For years, plasma processing has been used for doping. Plasma doping is sometimes referred to as PLAD or plasma immersion ion implantation (PIII). Plasma doping systems have been developed to meet the doping requirements of state-of-the-art electronic and optical devices.

Plasma doping systems are fundamentally different from conventional beam-line ion implantation systems that accelerate ions with an electric field and then filter the ions according to their mass-to-charge ratio to select the desired ions for implantation. In contrast, plasma doping systems immerse the target in a plasma containing dopant ions and bias the target with a series of negative voltage pulses. The term “target” is defined herein as the workpiece being implanted, such as a substrate or wafer being ion implanted. The negative bias on the target repels electrons from the target surface, thereby creating a sheath of positive ions. The electric field within the plasma sheath accelerates ions toward the target, thereby implanting the ions into the target surface.

The throughput of a plasma doping system is an important performance metric. The term “throughput” as used herein is defined as the dose provided to the substrate per unit time. The throughput is one important factor in determining the number of wafers per hour that can be processed with a plasma doping system. The value of a plasma doping system is often measured by the system throughput.

Throughput of a plasma doping system can be increased by increasing the dose per bias voltage pulse. The dose per bias voltage pulse can generally be increased by increasing the pulse width and/or frequency of the DC bias voltage pulses applied to the substrate. That is, the throughput of the plasma doping system can be adjusted using pulse width modulation (PWM).

Some existing methods of controlling the throughput of the plasma doping system via PWM use sensors to measure data related to conditions favorable for forming an electrical discharge. The pulse width of the bias voltage is altered, based on the sensor readings, to minimize the likelihood of forming an electrical discharge. However, there is a need for an alternative approach that doesn't require sensors.

### BRIEF SUMMARY

In one embodiment, the presently described subject matter provides a computer-implemented method including receiving, by a processing circuit, a duty cycle parameter from a user interface associated with the processing circuit. The method further includes generating, by the processing circuit, a control signal for a wafer pulse power supply of a plasma doping system to alter a pulse duty cycle of the wafer pulse power supply according to the duty cycle parameter. And the method further includes sending, by the processing circuit, the control signal to the wafer pulse power supply to thereby alter a duty cycle of a pulse signal generated by the wafer pulse power supply.

In another embodiment, a plasma doping system is provided, the plasma doping system including a memory having instructions stored thereon and a processing circuit to execute the instructions. When the instructions are executed by the processing circuit, they cause the processing circuit to receive a duty cycle parameter from a user interface associated with the processing circuit. They further cause the processing circuit to generate a control signal for a wafer pulse power supply of a plasma doping system to alter a pulse duty cycle of the wafer pulse power supply according to the duty cycle parameter. And they further cause the processing circuit to send the control signal to the wafer pulse power supply to thereby alter a duty cycle of a pulse signal generated by the wafer pulse power supply.

In yet another embodiment, a non-transitory computer-readable medium is provided and includes executable instructions stored thereon, which when executed by a processing circuit causes the processing circuit to receive a duty cycle parameter from a user interface associated with the processing circuit. Executing the instructions further cause the processing circuit to generate a control signal for a wafer pulse power supply of a plasma doping system to alter a pulse duty cycle of the wafer pulse power supply according to the duty cycle parameter. Executing the instructions further causes the processing circuit to send the control signal to the wafer pulse power supply to thereby alter a duty cycle of a pulse signal generated by the wafer pulse power supply.

Non-transitory computer program products (i.e., physically embodied computer program products) are also described that store instructions, which, when executed by one or more data processors (i.e., processing circuit) of one or more computing systems, cause at least one data processor to perform operations herein. Similarly, computer systems are also described, which may include one or more data processors and memory coupled to the one or more data processors. The memory may temporarily or permanently store instructions that cause at least one processor to perform one or more of the operations described herein. In addition, methods can be implemented by one or more data processors, which are either within a single computing system or distributed among two or more computing systems. Such computing systems can be connected and can exchange data and/or commands or other instructions or the like via one or more connections, including but not limited to a connection over a network (e.g., the Internet, a wireless wide area network, a local area network, a wide area network, a wired network, or the like), via a direct connection between one or more of the multiple computing systems, etc.

The details of one or more variations of the subject matter described herein are set forth in the accompanying drawings and the description below. Other features and advantages of the subject matter described herein will be apparent from the description and drawings, and from the claims.

### BRIEF DESCRIPTION OF THE SEVERAL VIEWS OF THE DRAWINGS

Provided below is a brief description of the several views of the drawings which illustrate various aspects of some embodiments of the present disclosure. The various drawings are described in more detail in the Detailed Description that follows. To easily identify the discussion of any particular element or act, the most significant digit or digits in a reference number refer to the figure number in which that element is first introduced.

FIG. 1 illustrates an example processing chamber in accordance with one embodiment.

FIG. 2 illustrates an example plasma doping system in accordance with one embodiment.

FIG. 3 illustrates an example doping profile and pulse graphs in accordance with one embodiment.

FIG. 4 illustrates an example wafer doping environment in accordance with one embodiment.

FIG. 5 is a flow chart illustrating an example method in accordance with one embodiment.

It should be understood that the drawings are not necessarily to scale and that the disclosed embodiments are sometimes illustrated diagrammatically and in partial views. In certain instances, details which are not necessary for an understanding of the disclosed methods and devices or which render other details difficult to perceive may have been omitted. It should be further understood that this disclosure is not limited to the particular embodiments illustrated herein. In the drawings, like numbers refer to like elements throughout unless otherwise noted.

### DETAILED DESCRIPTION

With general reference to notations and nomenclature used herein, one or more portions of the detailed description which follows may be presented in terms of program procedures executed on a computer or network of computers. These procedural descriptions and representations are used by those skilled in the art to most effectively convey the substances of their work to others skilled in the art. A procedure is here, and generally, conceived to be a self-consistent sequence of operations leading to a desired result. These operations are those requiring physical manipulations of physical quantities. Usually, though not necessarily, these quantities take the form of electrical, magnetic, or optical signals capable of being stored, transferred, combined, compared, and otherwise manipulated. It proves convenient at times, principally for reasons of common usage, to refer to these signals as bits, values, elements, symbols, characters, terms, numbers, or the like. It should be noted, however, that all of these and similar terms are to be associated with the appropriate physical quantities and are merely convenient labels applied to those quantities.

Useful machines for performing operations of various embodiments include digital computers as selectively activated or configured by a computer program stored within that is written in accordance with the teachings herein, and/or include apparatus specially constructed for the required purpose or a digital computer. Various embodiments also relate to apparatus or systems for performing these operations. These apparatuses may be specially constructed for the required purpose. The required structure for a variety of these machines will be apparent from the description given.

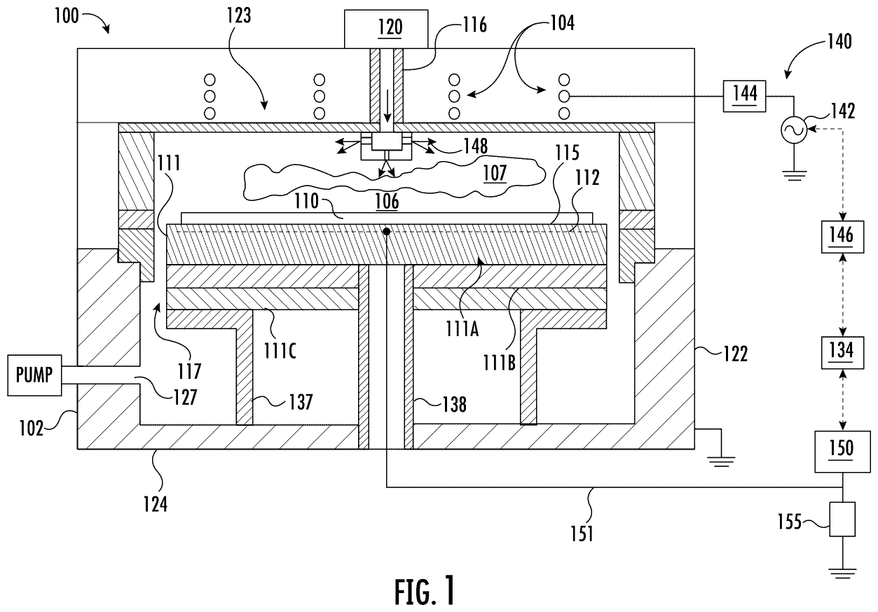

FIG. 1 is a cross-sectional view of a processing chamber 100 configured to perform a plasma process within a processing volume 106 of the processing chamber 100 by use of a source assembly 140, according to one embodiment. In this embodiment, the processing chamber 100 is a plasma processing chamber, such as a reactive ion etch (RIE) plasma chamber. In some other embodiments, the processing chamber 100 is a plasma-enhanced deposition chamber, for example a plasma-enhanced chemical vapor deposition (PECVD) chamber, a plasma enhanced physical vapor deposition (PEPVD) chamber, or a plasma-enhanced atomic layer deposition (PEALD) chamber. In some other embodiments, the processing chamber 100 is a plasma treatment chamber, or a plasma-based ion implant chamber, for example a plasma doping (PLAD) chamber. Herein, as shown in FIG. 1, the processing chamber 100 includes the source assembly 140 that includes an inductively coupled plasma (ICP) source electrically coupled to a radio frequency (RF) switch mode power supply 142 through a resonance circuit 144 (an RF matching circuit 144) under the control of a plasma controller 146. In other embodiments, the source assembly 140 is a capacitively coupled plasma (CCP) source, such as a source electrode (not shown) disposed in the processing volume 106 facing the substrate support 111, wherein the source electrode is electrically coupled to an RF power supply (not shown).

The processing chamber 100 includes a chamber body 102 which includes a chamber lid 123, one or more sidewalls 122, and a chamber bottom 124 which define a processing volume 106. A gas inlet 116 disposed through the chamber lid 123 is used to provide one or more processing gases 148 to the processing volume 106 from a processing gas source 120 in fluid communication therewith. Herein, a switch mode power supply 142 and a resonance circuit 144 are configured to ignite processing gases 148 into a plasma 107 under the control of the plasma controller 146. The processing chamber 100 further includes one or more inductive coils 104 disposed proximate to the chamber lid 123 outside of the processing volume 106. The switch mode power supply 142 and the resonance circuit 144 are used to ignite and maintain a plasma 107 using the processing gases 148 and electromagnetic field generated by the inductive coils 104 and switch mode power supply 142.

The processing volume 106 is fluidly coupled to one or more dedicated vacuum pumps, through a vacuum outlet 127, which maintain the processing volume 106 at sub-atmospheric conditions and evacuate processing, and/or other gases, therefrom. A substrate support assembly 117, disposed in the processing volume 106, is disposed on a support shaft 138 sealingly extending through the chamber base 124.

The substrate 110 is loaded into, and removed from, the processing volume 106 through an opening (not shown) in one of the one or more sidewalls 122, which is sealed with a door or a valve (not shown) during plasma processing of the substrate 110. Herein, the substrate 110 is transferred to and from a receiving surface 115 (e.g., substrate supporting surface) of a substrate support 111, which can include an ESC substrate support 111A using a lift pin system (not shown). The substrate support 111 includes a support base 111B and the ESC substrate support 111A that is thermally coupled to, and disposed on, the support base 111B. The support base 111B is electrically isolated from the chamber base 124 by an insulator plate 111C, and a ground plate 137 that is interposed between the insulator plate 111C and the chamber base 124. Typically, the support base 111B is used to regulate the temperature of the ESC substrate support 111A, and the substrate 110 disposed on the ESC substrate support 111A, during substrate processing. In some embodiments, the support base 111B includes one or more cooling channels (not shown) disposed therein that are fluidly coupled to, and in fluid communication with, a coolant source (not shown), such as a refrigerant source or water source having relatively high electrical resistance.

In some embodiments herein, the ESC substrate support 111A further includes a biasing electrode 112 embedded in the dielectric material thereof. In one configuration, the biasing electrode 112 is a chucking pole used to secure (chuck) the substrate 110 to the receiving surface 115 of the ESC substrate support 111A and to bias the substrate 110 with respect to the plasma 107. Typically, the biasing electrode 112 is formed of one or more electrically conductive parts, such as one or more metal meshes, foils, plates, or combinations thereof. Herein, the biasing electrode 112 is electrically coupled to a high voltage module 155 which provides a chucking voltage thereto, such as a periodic or rectangular waveform DC voltage between about −5000 V and about 5000 V, using an electrical conductor, such as the transmission line 151. Herein, a biasing electrode 112 is electrically coupled to the power generator 150 using the external conductor, such as the transmission line 151. The power generator 150 can be direct current (DC) power generator, a low frequency RF power generator or a shaped pulsed DC bias power generator. For example, the power generator can generate a rectangular voltage waveform using pulse width modulation techniques (PWM).

The processing chamber 100 further includes a system controller 134. In some embodiments, the system controller 134 herein includes a processing circuit (e.g., central processing unit (CPU)), a memory, and support circuits. The system controller 134 is used to control the process sequence used to process the substrate 110 including the substrate biasing methods described herein. The processing circuit can include a general purpose computer processor configured for use in an industrial setting for controlling processing chamber and sub-processors related thereto. The memory described herein may include random access memory (RAM), read only memory (ROM), a hard disk drive, solid-state memory, or other suitable forms of digital storage, local or remote. The support circuits are conventionally coupled to the processing circuit and comprise cache, clock circuits, input/output subsystems, power supplies, and the like, and combinations thereof. Software instructions and data can be coded and stored within the memory for instructing the processing circuit to perform various operations. A program (or computer instructions) readable by the system controller 134 determines which tasks are performable by the components in the processing chamber 100. Preferably, the program, which is readable by the system controller 134, includes code, which when executed by the processing circuit, perform tasks relating to control the various hardware and electrical components within the processing chamber 100 to perform the various process tasks and various process sequences used to implement the electrode biasing scheme described herein.

In some embodiments, the system controller 134 can also control the power generator to determine the pulse width or duty cycle (duty factor) of a voltage signal created by the power generator.

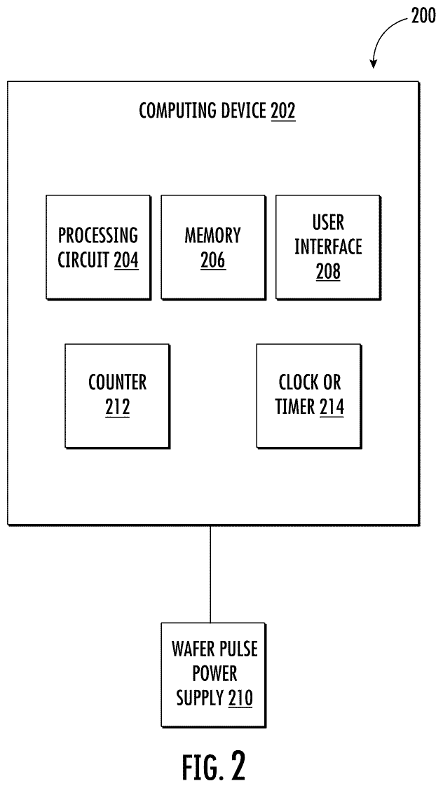

FIG. 2 is a block diagram illustrating an example plasma doping system 200, according to some embodiments of the present disclosure. The plasma doping system 200 depicted in FIG. 2 does not include all components of a plasma doping system 200, but instead includes a specific section thereof. More particularly, FIG. 2 depicts the device that sends the voltage pulses and a control mechanism therefor.

For example, in some embodiments, the plasma doping system 200 includes a computing device 202 for controlling pulses sent by a wafer pulse power supply 210. In some embodiments, the computing device 202 may be equivalent to the system controller 134 in FIG. 1. Additionally, the wafer pulse power supply 210 may be equivalent to the high voltage module 155 or the power generator 150 of FIG. 1. The wafer pulse power supply 210 provides voltage pulses to the biasing electrode 112 (e.g., of the semiconductor wafer) to cause a potential difference (e.g., biasing voltage) between the biasing electrode 112 and the plasma, during a doping process thereof. The biasing voltage is configured to provide sufficient energy to implant ions into the semiconductor wafer.

In some embodiments, the computing device 202 of the plasma doping system 200 includes a memory 206 having instructions stored thereon as well as a processing circuit processing circuit 204 to execute the instructions. When the instructions are executed by the processing circuit 204, the processing circuit 204 is caused to perform various operations. For example, in some embodiments, the processing circuit 204 is configured to receive a duty cycle parameter from a user interface 208 associated with the processing circuit processing circuit 204. In some embodiments, the user interface is a mouse, keyboard, touch screen, graphical user interface (GUI), button, keypad, or any other suitable user interface 208.

As one example, the instructions include instructions for a software application that operates a GUI to be displayed on a monitor or screen for a user of the computing device 202. The user can select, alter, or enter (e.g., via their mouse, keyboard, etc.) the duty cycle parameter into the GUI. Alternatively, the duty cycle parameter can be obtained from another computing device via a message from the other computing device. For example, the user can send a message to the computing device 202 with the duty cycle parameter.

The duty cycle parameter can be any parameter changing, setting, or altering a duty cycle for a voltage signal generated by the wafer pulse power supply 210. The duty cycle parameter can indicate when the duty cycle is changed, for example after a predetermine amount of time. For example, the GUI of the software application can include a parameter indicating a predetermine time, the predetermined time being how long the computing device 202 will wait before altering the duty cycle of the waveform to be generated by the wafer pulse power supply 210. For example, the user can select in the GUI that every 100 milliseconds, the duty cycle goes up by 10%.

As discussed above, in some embodiments, the duty cycle parameter includes a plurality of duty cycle parameters. Using the above GUI and software application, the GUI can allow the user to select the duty cycle percentage at a plurality of steps, and then select the times between each step. In some embodiments, each of the plurality of duty cycle parameters includes a unique duty cycle ratio of the pulse signal that is selectable at the user interface. In some embodiments, the plurality of duty cycle parameters includes a first duty cycle parameter and one or more subsequent duty cycle parameters with increasing duty cycle. For example, the user can select that the duty cycle of the waveform will be 10%, 20%, 30%, 40%, 50%, and 60% at 100 microseconds, 250 microseconds, 300 microseconds, 350 microseconds, 450 microseconds, 500 microseconds, and 600 microseconds after the waveform begins, respectively.

In response to the computing device 202 receiving the duty cycle parameter, the processing circuit 204 is configured to generate a control signal for the wafer pulse power supply 210 of the plasma doping system 200 to alter a pulse duty cycle of the wafer pulse power supply 210 according to the duty cycle parameter. For example, the wafer pulse power supply 210 may start at a duty cycle of 0% whereby the voltage of the waveform is constantly at OV or an otherwise very low voltage. The control signal is generated by the processing circuit 204 to cause the duty cycle of the wafer pulse power supply 210 to be altered from, for example, 0% to 10% based on the parameters set in the duty cycle parameter.

The processing circuit 204 is then configured to send the control signal to the wafer pulse power supply 210 to thereby alter the duty cycle of a pulse signal generated by the wafer pulse power supply 210. Upon the wafer pulse power supply 210 receiving the control signal, the wafer pulse power supply 210 is to process the control signal and alter the duty cycle of the pulse waveform it generates based on the control signal.

In some embodiments, a user may wish to alter the duty cycle based on a number of pulses sent by the 210. In such embodiments, the duty cycle parameter includes a predetermined number of pulses sent by the wafer pulse power supply 210 (e.g., the number of pulses before the duty cycle is to be changed). The processing circuit 204 is configured to maintain a counter 212 of a number of pulses sent by the wafer pulse power supply 210. In some embodiments, once the counter 212 determines that the number of pulses sent by the wafer pulse power supply 210 has exceed the number of predetermined pulses, the control signal is generated and sent to alter the duty cycle of the wafer pulse power supply 210 pulses.

In some embodiments, the processing circuit 204 maintains a clock or timer 214 and the duty cycle parameter includes a predetermined amount of time. In such an embodiment, the processing circuit 204 is configured to generate the control signal in response to the clock or timer 214 indicating that the predetermined amount of time has passed.

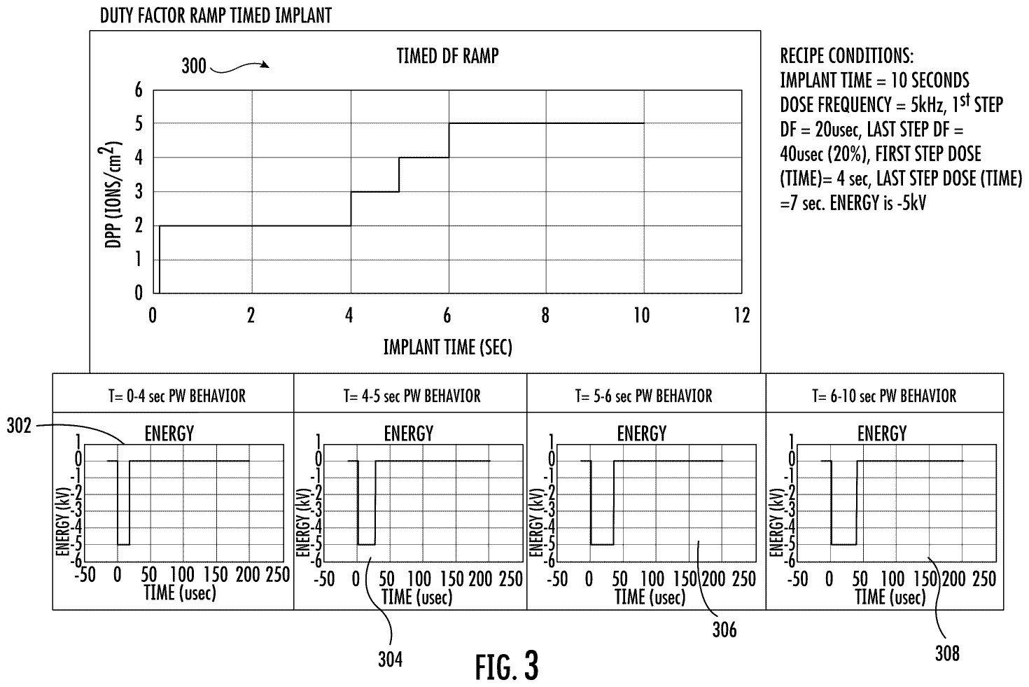

In some embodiments, the duty cycle parameter is selected such that the generated control signal causes the pulse duty cycle to generate a doping profile in an experimental wafer to match a predetermined doping profile. Such a doping profile is illustrated in FIG. 3.

FIG. 3 illustrates an example doping profile 300. As discussed above, in some embodiments, the duty cycle parameter can be selected to match a particular doping profile, such as doping profile 300. Doping profile 300 shows the doping per pulse for an example wafer, where for each pulse, the number of ions per cubic centimeter are increased. That is, as the pulses from the wafer pulse power supply 210 in FIG. 2. Are generated, the ions are implanted into the wafer at the rate shown in the doping profile 300. On the x-axis, the amount of time from the start of doping (i.e., 0 sec) that has elapsed. For example, at time t=4 seconds, the doping per pulse (DPP) increases from about 2 DPP to about 3 DPP.

Below the doping profile 300 are four graphs, first pulse graph 302, second pulse graph 304, third pulse graph 306, and fourth pulse graph 308. Each of these graphs represent the pulse that was sent by the wafer pulse power supply 210 to the wafer. As shown at first pulse graph 302, the voltage provided is a negative voltage pulse. That is, the voltage graph in first pulse graph 302 is at 0 volts most of the time, and at time t=0 microsecs, there is a negative pulse down to −5 kV. Each of first pulse graph 302, second pulse graph 304, third pulse graph 306, and fourth pulse graph 308 have negative pulses that provide a −5 kV pulse.

As shown in doping profile 300, the doping profile has four steps up (e.g., one at 0 seconds, one at 4 sec, one at 5 sec, and one at 6 sec). These four steps up correspond to the four pulse graphs, first pulse graph 302, second pulse graph 304, third pulse graph 306, and fourth pulse graph 308. That is, the pulse shown at first pulse graph 302 causes the first step up at 0 seconds, the second pulse graph 304 causes the second step up at 4 seconds, the third pulse graph 306 causes the third step up at 5 seconds, and the fourth pulse graph 308 causes the fourth step up at 6 seconds.

Each of the first pulse graph 302, second pulse graph 304, third pulse graph 306, and fourth pulse graph 308 have a different duty cycle as shown by a width of the negative pulse. These duty cycles and the time at which the pulses were sent can be determined and used to match a doping profile such as doping profile 300. For example, an expected doping profile can be known and the different pulses can be selected using the duty cycle parameter to match the expected doping profile.

In some embodiments, the profile matching implementation is performed using a time-based plasma doping system that can replicate an existing dosed duty cycle ramp implant. In other embodiments, the profile matching implementation is performed using a frequency-based plasma doping system that can replicate an existing dosed duty cycle ramp implant.

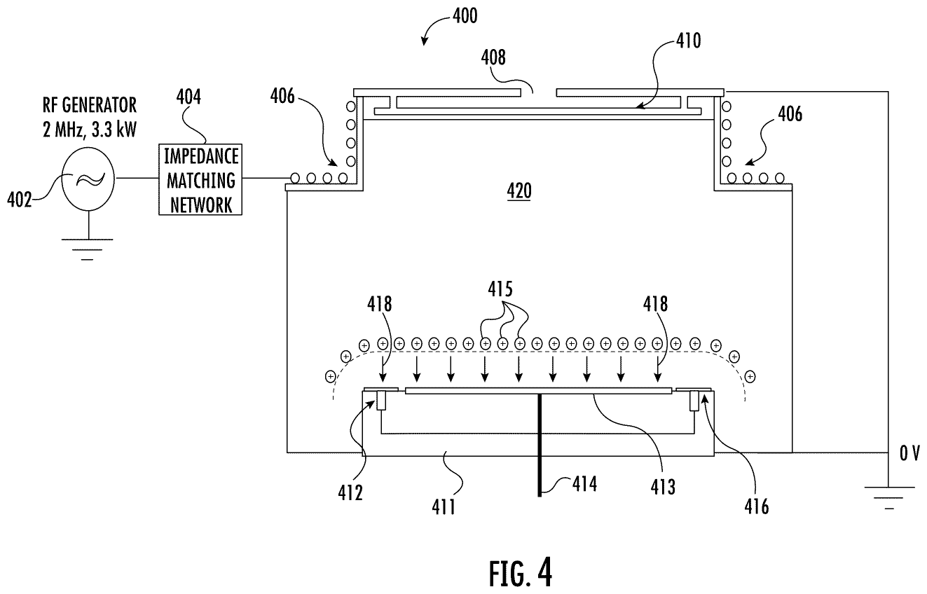

FIG. 4 illustrates an example wafer doping environment 400. In some embodiments, the wafer doping environment 400 includes a radio frequency (RF) generator 402 which operates at any suitable frequency. In some embodiments, the RF generator 402 operates at a frequency of between 1 MHz and 5 MHz. As shown in the figure, one example frequency is 2 MHz. The RF generator 402 further operates at any suitable power level. In some embodiments, the RF generator 402 can operate at a power of between 1 kW to 5 kW. For example, as shown in the figure, in some embodiments, the RF generator 402 operates at 3.3 kW. The wafer pulse power supply 210 from FIG. 2 can include the RF generator 402 from FIG. 4 as well as an impedance matching network 404. The RF generator 402 can be controlled by plasma doping system 200.

In some embodiments, the wafer doping environment 400 may include one or more RF coil sets 406. As shown in FIG. 406, the RF coil sets 406 can be horizontally oriented with respect to a flat surface of the wafer 411 that faces the plasma 420, or the RF coil sets 406 can be vertically oriented with respect to the flat surface of the wafer 411. In some embodiments, either the horizontally oriented RF coils or the vertically oriented coils can be used or both can be used at the same time. In some embodiments, just the horizontally oriented RF coils are used as described herein. In some embodiments, the RF coil sets 406 are used to generate a high-frequency electromagnetic field. This field is used for various purposes in semiconductor processing, such as, plasma generation, plasma confinement, and plasma heating. In plasma processing, the RF coil sets 406 are typically used to induce a plasma in the chamber. The high frequency electromagnetic field generated by the coil ionizes the gas in the chamber, creating a plasma 420. This plasma 420 is then used for various processes, such as etching, deposition, or implantation of thin films on semiconductor wafers. The RF coil sets 406 play a role in creating, controlling, and heating the plasma 420 used in semiconductor processing, supporting various manufacturing steps, including those described herein.

The wafer doping environment 400 further includes a gas inlet 408 and water-cooled baffle or dispenser 410. The gas inlet 408 is used to permit gases to enter the chamber such as oxygen, nitrogen, argon, hydrogen, or compressed air to enter the chamber to help generate the plasma 420. The water-cooled baffle or dispenser 410 is used to cool the gas. The chamber shown in FIG. 4 can be similar to the processing chamber 100 from FIG. 1.

In some embodiments, the wafer doping environment 400 further includes a wafer 411 to be doped. The wafer 411 can be made of any suitable substance. For example, the wafer 411 can be comprised of a semiconductor such as silicon, germanium, or gallium arsenide. The wafer 411 can be disposed within the chamber and surrounded by the plasma 420.

In some embodiments, the wafer 411 can include a dosimetry system faraday cup 412. The faraday cup 412 may be used to monitor the beam current determination of the ion source. In some other embodiments, the wafer includes a negative high voltage pulse rail 414 that connects to a biasing electrode 413. The high voltage pulse rail 414 connects to the electrode 413 on the wafer 411 and the high voltage pulse rail 414 sends a negative high voltage pulse to the electrode 413 which biases the electrode 413 and creates the potential difference between the biasing electrode 413 and the plasma 420. The potential difference causes the ions 415 to implant on the wafer 411 as shown by the arrows 418. In some embodiments, the electrode 413 may include a bulk silicon or silicon carbide shield ring 416.

In some embodiments, the wafer pulse power supply 210 from FIG. 2 can be separate from the RF Generator 402 and be a separate power supply (not shown). The wafer pulse power supply 210 from FIG. 2 can be configured to provide the pulses of the high voltage pulse rail 414. The wafer pulse power supply 210 that provides the pulses of the high voltage pulse rail 414 to bias the voltage of the electrode 413 can be controlled by plasma doping system 200 from FIG. 2. In some embodiments, the plasma doping system 200 from FIG. 2 can be used to operate either or both of the RF generator 402 and the high voltage pulse rail 414.

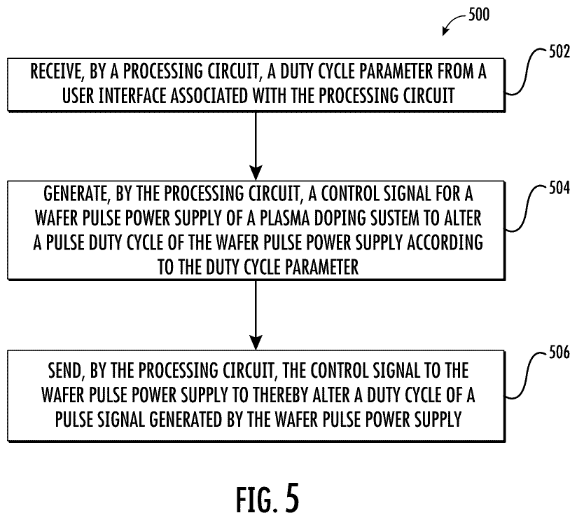

FIG. 5 is a flow diagram illustrating various steps in a method 500 for duty factor ramped timed ion implant matching. As shown at block 502, the method 500 includes receiving, by a processing circuit, a duty cycle parameter from a user interface associated with the processing circuit. As shown at block 504, the method 500 includes generating, by the processing circuit, a control signal for a wafer pulse power supply of a plasma doping system to alter a pulse duty cycle of the wafer pulse power supply according to the duty cycle parameter. As shown at block 506, the method 500 includes sending, by the processing circuit, the control signal to the wafer pulse power supply to thereby alter a duty cycle of a pulse signal generated by the wafer pulse power supply.

In some embodiments of the method 500, the duty cycle parameter includes a plurality of duty cycle parameters. In some embodiments, each of the plurality of duty cycle parameters includes a unique duty cycle ratio of the pulse signal that is selectable at the user interface. In some embodiments, the plurality of duty cycle parameters includes a first duty cycle parameter and one or more subsequent duty cycle parameters with increasing duty cycle.

In some embodiments of the method 500, the duty cycle parameter includes a predetermined number of pulses sent by the wafer pulse power supply, and the method 500 further includes maintaining, by the processing circuit, a counter of a number of pulses sent by the wafer pulse power supply, wherein the control signal is generated in response to the counter exceeding the predetermined number of pulses.

In some embodiments of the method 500, the duty cycle parameter includes a predetermined amount of time, and the method further includes maintaining, by the processing circuit, a clock or timer, wherein the control signal is generated in response to the clock or timer indicating that the predetermined amount of time has passed.

In some embodiments of the method 500, the duty cycle parameter is selected such that the generated control signal causes the pulse duty cycle to generate a doping profile in an experimental wafer to match a predetermined doping profile. In some embodiments, the user interface is executed by a computer application of a computing device in communication with the processing circuit, the user interface having one or more selectable and alterable duty cycle parameter options. And in some embodiments, the wafer pulse power supply is to provide a biasing voltage to a semiconductor wafer during a doping process thereof, the biasing voltage configured to provide sufficient energy to implant ions into the semiconductor wafer.

Some embodiments of the disclosed system may be implemented, for example, using a storage medium, a computer-readable medium or an article of manufacture which may store an instruction or a set of instructions that, when executed by a machine (e.g., processor, processing circuit, or microcontroller), may cause the machine to perform a method and/or operations in accordance with embodiments of the disclosure. In addition, a server or database server may include machine readable media configured to store machine executable program instructions. Such a machine may include, for example, any suitable processing platform, computing platform, computing device, processing device, computing system, processing system, computer, processor, or the like, and may be implemented using any suitable combination of hardware, software, firmware, or a combination thereof and utilized in systems, subsystems, components, or sub-components thereof.

The various elements of the devices as previously described with reference to the figures above may include various hardware elements, software elements, or a combination of both. Examples of hardware elements may include devices, logic devices, components, processors, microprocessors, circuits, processors, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. Examples of software elements may include software components, programs, applications, computer programs, application programs, system programs, software development programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. However, determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

One or more aspects of at least one embodiment may be implemented by representative instructions stored on a non-transitory machine-readable medium which represents various logic within the processor, which when read by a machine causes the machine to fabricate logic to perform the techniques described herein. Such representations, known as “IP cores” may be stored on a tangible, machine readable medium and supplied to various customers or manufacturing facilities to load into the fabrication machines that make the logic or processor. Some embodiments may be implemented, for example, using a machine-readable medium or article which may store an instruction or a set of instructions that, if executed by a machine, may cause the machine to perform a method and/or operations in accordance with the embodiments. Such a machine may include, for example, any suitable processing platform, computing platform, computing device, processing device, computing system, processing system, computer, processor, or the like, and may be implemented using any suitable combination of hardware and/or software. The machine-readable medium or article may include, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions may include any suitable type of code, such as source code, compiled code, interpreted code, executable code, static code, dynamic code, encrypted code, and the like, implemented using any suitable high-level, low-level, object-oriented, visual, compiled and/or interpreted programming language.

As used herein, an element or operation recited in the singular and proceeded with the word “a” or “an” should be understood as not excluding plural elements or operations, unless such exclusion is explicitly recited. Furthermore, references to “one embodiment” of the present disclosure are not intended to be interpreted as excluding the existence of additional embodiments that also incorporate the recited features.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

What is claimed is:

1. A computer implemented method comprising:
receiving, by a processing circuit, a duty cycle parameter from a user interface associated with the processing circuit;
generating, by the processing circuit, a control signal for a wafer pulse power supply of a plasma doping system to alter a pulse duty cycle of the wafer pulse power supply according to the duty cycle parameter; and
sending, by the processing circuit, the control signal to the wafer pulse power supply to thereby alter a duty cycle of a pulse signal generated by the wafer pulse power supply.

2. The computer implemented method of claim 1, wherein the duty cycle parameter includes a plurality of duty cycle parameters.

3. The computer implemented method of claim 2, wherein each of the plurality of duty cycle parameters includes a unique duty cycle ratio of the pulse signal that is selectable at the user interface.

4. The computer implemented method of claim 2, wherein the plurality of duty cycle parameters includes a first duty cycle parameter and one or more subsequent duty cycle parameters with increasing duty cycle.

5. The computer implemented method of claim 1, wherein the duty cycle parameter includes a predetermined number of pulses sent by the wafer pulse power supply, and wherein the method further comprises:
maintaining, by the processing circuit, a counter of a number of pulses sent by the wafer pulse power supply;
wherein the control signal is generated in response to the counter exceeding the predetermined number of pulses.

6. The computer implemented method of claim 1, wherein the duty cycle parameter includes a predetermined amount of time, and wherein the method further comprises:
maintaining, by the processing circuit, a clock or timer;
wherein the control signal is generated in response to the clock or timer indicating that the predetermined amount of time has passed.

7. The computer implemented method of claim 1, wherein the duty cycle parameter is selected such that the generated control signal causes the pulse duty cycle to generate a doping profile in an experimental wafer to match a predetermined doping profile.

8. The computer implemented method of claim 1, wherein the user interface is executed by a computer application of a computing device in communication with the processing circuit, the user interface having one or more selectable and alterable duty cycle parameter options.

9. The computer implemented method of claim 1, wherein the wafer pulse power supply is to provide a biasing voltage to a semiconductor wafer during a doping process thereof, the biasing voltage configured to provide sufficient energy to implant ions into the semiconductor wafer.

10. A plasma doping system comprising:
a memory having instructions stored thereon;
a processing circuit to execute the instructions, which when executed by the processing circuit causes the processing circuit to;
receive a duty cycle parameter from a user interface associated with the processing circuit;
generate a control signal for a wafer pulse power supply of a plasma doping system to alter a pulse duty cycle of the wafer pulse power supply according to the duty cycle parameter; and
send the control signal to the wafer pulse power supply to thereby alter a duty cycle of a pulse signal generated by the wafer pulse power supply.

11. The plasma doping system of claim 10, wherein the duty cycle parameter includes a plurality of duty cycle parameters;
wherein each of the plurality of duty cycle parameters includes a unique duty cycle ratio of the pulse signal that is selectable at the user interface; and
wherein the plurality of duty cycle parameters includes a first duty cycle parameter and one or more subsequent duty cycle parameters with increasing duty cycle.

12. The plasma doping system of claim 10, wherein the duty cycle parameter includes a predetermined number of pulses sent by the wafer pulse power supply, and wherein the processing circuit is further caused to:
maintain a counter of a number of pulses sent by the wafer pulse power supply, wherein the control signal is generated in response to the counter exceeding the predetermined number of pulses.

13. The plasma doping system of claim 10, wherein the duty cycle parameter includes a predetermined amount of time, and wherein the processing circuit is further caused to:
maintaining a clock or timer, wherein the control signal is generated in response to the clock or timer indicating that the predetermined amount of time has passed.

14. The plasma doping system of claim 10, wherein the user interface is generated by a computer application executed by the processing circuit, the user interface having one or more selectable and alterable duty cycle parameter options; and
wherein the duty cycle parameter is selected from among the one or more selectable and alterably duty cycle parameter options such that the generated control signal causes the pulse duty cycle to generate a doping profile in an experimental wafer to match a predetermined doping profile.

15. The plasma doping system of claim 10, wherein the wafer pulse power supply is to provide a biasing voltage to a semiconductor wafer during a doping process thereof, the biasing voltage configured to provide sufficient energy to implant ions into the semiconductor wafer.

16. A non-transitory computer-readable storage medium having executable instructions stored thereon, which when executed by a processing circuit causes the processing circuit to:
receive a duty cycle parameter from a user interface associated with the processing circuit;
generate a control signal for a wafer pulse power supply of a plasma doping system to alter a pulse duty cycle of the wafer pulse power supply according to the duty cycle parameter; and
send the control signal to the wafer pulse power supply to thereby alter a duty cycle of a pulse signal generated by the wafer pulse power supply.

17. The non-transitory computer-readable storage medium of claim 16, wherein the wafer pulse power supply is to provide a biasing voltage to a semiconductor wafer during a doping process thereof, the biasing voltage configured to provide sufficient energy to implant ions into the semiconductor wafer;
wherein the duty cycle parameter includes a plurality of duty cycle parameters;
wherein each of the plurality of duty cycle parameters includes a unique duty cycle ratio of the pulse signal that is selectable at the user interface; and
wherein the plurality of duty cycle parameters includes a first duty cycle parameter and one or more subsequent duty cycle parameters with increasing duty cycle.

18. The non-transitory computer-readable storage medium of claim 16, wherein the duty cycle parameter includes a predetermined number of pulses sent by the wafer pulse power supply, and wherein the processing circuit is further caused to:
maintain a counter of a number of pulses sent by the wafer pulse power supply, wherein the control signal is generated in response to the counter exceeding the predetermined number of pulses.

19. The non-transitory computer-readable storage medium of claim 16, wherein the duty cycle parameter includes a predetermined amount of time, and wherein the processing circuit is further caused to:
maintain a clock or timer, wherein the control signal is generated in response to the clock or timer indicating that the predetermined amount of time has passed.

20. The non-transitory computer-readable storage medium of claim 16, wherein the user interface is generated by a computer application executed by the processing circuit, the user interface having one or more selectable and alterable duty cycle parameter options; and
wherein the duty cycle parameter is selected from among the one or more selectable and alterably duty cycle parameter options such that the generated control signal causes the pulse duty cycle to generate a doping profile in an experimental wafer to match a predetermined doping profile.
